(19) United States
(12) Patent Application Publication
(10) Pub. No.: US 2026/0275499 A1
(43) Pub. Date: Sep. 17, 2026

(54) PVD Device with Adjustable Rotation Radius of Magnetron and Source Power Applied to Planar Target and Application Method Thereof

(71) Applicant: ARRAYED MATERIALS (CHINA) CO.,LTD., Shenzhen (CN)

(72) Inventors: Hong Sheng Yang, Shenzhen (CN); Xinhua Zhu, Shenzhen (CN); Shouxiang Sun, Shenzhen (CN); Xiaojun Zhang, Shenzhen (CN)

(21) Appl. No.: 19/162,525

(22) PCT Filed: May 29, 2023
(86) PCT No.: PCT/CN2023/096867

§ 371 Date: Sep. 5, 2025

(30) Foreign Application Priority Data
Mar. 6, 2023 (CN) 202310250018.6

(51) Int. Cl. C23C 14/34; C23C 14/35; C23C 14/54

(52) U.S. Cl. CPC C23C 14/3492; C23C 14/3435; C23C 14/35; C23C 14/545

(57) ABSTRACT

A PVD device with adjustable rotation radius of a magnetron and source power applied to a planar target and an application method thereof are disclosed. The device includes: a magnetron rotating assembly including a magnetron slidably connected to a bracket via a guide rail and a slider for the magnetron, and a projection area of the magnetron is smaller than that of the planar target on a horizontal plane; a drive mechanism including a first drive unit configured to drive the magnetron to rotate along a circumferential trajectory and a second drive unit configured to drive the magnetron to move radially relative to the magnetron bracket, thereby adjusting the radius of the circumferential trajectory; and a controller configured to perform at least one of the following: control the second drive unit to drive the magnetron to move radially; or control a source power applied to the planar target.

### CROSS-REFERENCE TO RELATED APPLICATIONS

This application is the United States national phase of International Patent Application No. PCT/CN2023/096867 filed on May 29, 2023, and claims priority to Chinese Patent Application No. 202310250018.6 filed on Mar. 6, 2023, the disclosures of which are hereby incorporated by reference in their entireties.

### BACKGROUND

### Technical Field

The present disclosure relates to the technical field of film coating devices, and in particular, to a PVD device with adjustable rotation radius of magnetron and source power of a planar target and application method thereof.

### Technical Considerations

In related technologies, physical vapor deposition (PVD) technology denotes a process that, under vacuum conditions, a solid source material is vaporized into gaseous atoms or molecules, or partially ionized into ions, and subsequently deposited onto a surface of a substrate to form functional films through a low-pressure gas (or plasma) environment.

In the existing PVD coating device, the coating formed on the substrate frequently exhibits non-uniform resistivity and thickness distribution, which adversely affects film quality and fails to meet production yield requirements.

### SUMMARY

The present disclosure aims to solve at least one of the technical problems existing in the existing technologies. To this end, a PVD device with adjustable rotation radius of magnetron and source power of a planar target is proposed in the present disclosure, which can effectively solve the non-uniform resistivity and thickness problem of the coating film on the substrate.

A method for adjusting a rotation radius of a PVD magnetron and a source power applied to a planar target is further proposed in the present disclosure.

According to a non-limiting embodiment in a first non-limiting aspect of the present disclosure, a PVD device with adjustable rotation radius of magnetron and source power of a planar target is applied to form a film on a substrate, and the device includes:
a magnetron rotating assembly, including a magnetron, a magnetron bracket, a magnetron guide rail and a magnetron slider, where the magnetron is slidably connected to the magnetron bracket via the magnetron guide rail and the magnetron slider, where a projection area of the magnetron on a horizontal plane is smaller than a projection area of the planar target on the horizontal plane;
a drive mechanism, including a first drive unit and a second drive unit, where the first drive unit is configured to drive the magnetron bracket to rotate around a first axis, such that the magnetron rotates relative to the planar target along a circumferential trajectory, and the second drive unit is configured to drive the magnetron to move radially relative to the magnetron bracket, thereby adjusting the radius of the circumferential trajectory; and
a controller configured to perform at least one of the following control logics:
controlling the second drive unit to drive the magnetron to move radially, such that the film is formed with a thickness within a set thickness range; or
controlling a source power applied to the planar target, such that the film is formed with a resistivity within a set resistivity range.

The PVD device with adjustable rotation radius of magnetron and source power of a planar target according to a non-limiting embodiment of the present disclosure has at least the following beneficial effects:
the device can drive the magnetron to move radially relative to the magnetron bracket, thereby adjusting the rotation radius of the circumferential trajectory of the magnetron and enabling the film thickness uniformity across the substrate. In addition, controlling the source power applied to the planar target enables the film resistivity uniformity across the substrate with a high speed of testing parameter adjustment, and the experimental efficiency can be improved.

According to some non-limiting embodiments of the present disclosure, the drive mechanism further includes a first link and a second link, the first link is rotatably connected at both ends to the second link and the magnetron slider, respectively, and the second link is capable of rotating around a second axis, such that the magnetron is driven to move radially via the first link to adjust the rotation radius of the circumferential trajectory, where the first axis and the second axis are disposed in parallel.

According to some non-limiting embodiments of the present disclosure, the drive mechanism further includes a first shaft and a second shaft, the first shaft is connected to a shaft output end of the first drive unit and the magnetron bracket, and the second shaft is connected to a shaft output end of the second drive unit and the second link; and
the first shaft and the second shaft are arranged coaxially, the first axis coincides with the second axis, the first drive unit is capable of driving the first shaft to rotate, such that the magnetron rotates relative to the planar target along the circumferential trajectory, and the second drive unit is capable of driving the second shaft to rotate to adjust the rotation radius of the magnetron.

According to some non-limiting embodiments of the present disclosure, the drive mechanism further includes a first shaft pin, and the magnetron slider is rotatably connected to the first link via the first shaft pin.

According to some non-limiting embodiments of the present disclosure, the drive mechanism further includes a second shaft pin, and the first link is rotatably connected to the second link via the second shaft pin; and
the magnetron bracket has a first arc-shaped groove, an end of the second shaft pin protrudes from a surface of the first link and is positioned in the first arc-shaped groove, and the first arc-shaped groove is capable of guiding the second shaft pin.

According to some non-limiting embodiments of the present disclosure, the device further includes a counterweight rotating assembly that includes a counterweight block, a counterweight bracket, a counterweight guide rail and a counterweight slider, and the counterweight block is slidably connected to the counterweight bracket via the counterweight guide rail and the counterweight slider;
the first drive unit is configured to drive the counterweight bracket to rotate around the first axis, such that the counterweight block rotates along the circumferential trajectory, and the second drive unit is configured to drive the counterweight block to move radially relative to the counterweight bracket; and
the counterweight block and the magnetron move synchronously and in opposite directions, and the counterweight block and the magnetron are symmetrically arranged.

According to some non-limiting embodiments of the present disclosure, the drive mechanism further includes a first link and a second link, the first link is rotatably connected at both ends to the second link and the magnetron slider, respectively, and the second link is capable to rotating around the second axis, such that the magnetron is driven to move radially via the first link to adjust the rotation radius of the circumferential trajectory; and
the drive mechanism further includes a third link and a fourth link, the third link is rotatably connected at both ends to the fourth link and the counterweight slider, respectively, the fourth link is fixedly connected to the second link, and the fourth link and the second link are capable of rotating synchronously around the second axis, such that the counterweight block is driven to move radially via the third link to adjust the rotation radius of the circumferential trajectory.

According to some non-limiting embodiments of the present disclosure, the device further includes an adjustment assembly that is configured for adjusting a distance between a backing plate of the planar target and the magnetron.

According to a non-limiting embodiment in a second non-limiting aspect of the present disclosure, a method for adjusting a rotation radius of a PVD magnetron and source power applied to a planar target is applied to form a film on a substrate, and the method includes the following steps:
providing the magnetron and the planar target, where a projection area of the magnetron on a horizontal plane is smaller than a projection area of the planar target on the horizontal plane, and the magnetron is capable of rotating around a first axis relative to the planar target; and
adjusting the rotation radius of the magnetron, and/or adjusting the source power applied to the planar target, such that the film is formed with a thickness and a resistivity each within their respective set ranges.

The method for adjusting the rotation radius of the PVD magnetron and the source power applied to the planar target according to a non-limiting embodiment of the present disclosure has at least the following beneficial effects:

According to the method, the magnetron can be driven to move radially to adjust the rotation radius of the circumferential trajectory of the magnetron, which enables the film thickness uniformity across the substrate. In addition, controlling the source power applied to the planar target enables the film resistivity uniformity across the substrate with a high speed of testing parameter adjustment, and the experimental efficiency can be improved.

According to some non-limiting embodiments of the present disclosure, the method further includes the following steps:
acquiring thickness distribution information and resistivity distribution information of the film; and
adjusting the rotation radius of the magnetron, and/or adjusting the source power applied to the planar target, based on the thickness distribution information and the resistivity distribution information.

Additional aspects and advantages of the present disclosure will be set forth in part in the description which follows, and in part will be apparent from the description, or may be learned by practice of the present disclosure.

### BRIEF DESCRIPTION OF THE DRAWINGS

The present disclosure will be further described below in conjunction with the accompanying drawings and non-limiting embodiments, where:

FIG. 1 is a schematic diagram of a PVD device in the prior art;

FIG. 2 is a schematic diagram of a PVD device with adjustable rotation radius of magnetron and source power of a planar target according to some non-limiting embodiments of the present disclosure;

FIG. 3 is a cross-sectional view of a device PVD device with adjustable rotation radius of magnetron and source power of a planar target according to some non-limiting embodiments of the present disclosure;

FIG. 4 is a schematic diagram of a magnetron rotating assembly and a counterweight rotating assembly of a PVD device with adjustable rotation radius of magnetron and source power of a planar target according to some non-limiting embodiments of the present disclosure;

FIG. 5 is a schematic diagram of FIG. 4 from another perspective;

FIG. 6 is a schematic diagram of how a PVD device with adjustable rotation radius of magnetron and source power of a planar target improves the thickness and resistivity uniformity of a coating on a substrate according to some non-limiting embodiments of the present disclosure; and

FIG. 7 is a flow chart of a method for adjusting a rotation radius of a PVD magnetron and source power applied to a planar target according to some non-limiting embodiments of the present disclosure.

### REFERENCE NUMERALS

magnetron sputtering device 20, magnetron 22, vacuum chamber 24, planar target 26, substrate pedestal 28, substrate 30, mass flow controller 32, plasma 34;

A PVD device 40 with adjustable rotation radius of magnetron and source power of a planar target;
magnetron and counterweight rotating assembly 50, first drive unit 52, second drive unit 54, third drive unit 56, planar target 58, magnetron 60, first magnet 62, second magnet 64, yoke 66, cooling water tank 68, counterweight block 70, magnetron rotating assembly 80, and counterweight rotating assembly 90;
magnetron slider 100, magnetron guide rail 102, magnetron bracket 104, first link 106, second link 108, first arc-shaped groove 110, first shaft pin 112, first through hole 114, second shaft pin 116, second through hole 118, counterweight slider 120, counterweight guide rail 122, counterweight bracket 124, third link 126, fourth link 128, second arc-shaped groove 130, third shaft pin 132, third through hole 134, fourth shaft pin 136, fourth through hole 138, framework oil seal 140, magnetic fluid sealing shaft 142, first shaft 144, fifth through hole 146, and second shaft 148; and
substrate 200, magnetic induction line 210, film resistivity distribution curve 220 obtained by the prior art, the middle position 230 of the magnetron between the central and peripheral positions, the center position 240 of the magnetron, the outside position 250 of the magnetron, and optimized film resistivity distribution curve 260 of the present disclosure.

### DETAILED DESCRIPTION

Embodiments of the present disclosure will be described in detail below. Examples of the embodiments are illustrated in the accompanying drawings, where the same or like reference numerals throughout the figures indicate the same or like elements having the same or like functions. The embodiments described below with reference to the accompanying drawings are exemplary and are intended only to explain the present disclosure instead of being construed as limiting the present disclosure.

In the description of the present disclosure, it should be understood that, descriptions relating to orientation, for example, orientation or positional relationships are based on the orientation or positional relationships shown in the accompanying drawings, and are to facilitate the description of the present disclosure and simplify the description only, rather than indicating or implying that the device or element referred to must have a specific orientation or be constructed and operated in a specific orientation, and therefore cannot be construed as limiting the present disclosure.

In the description of the present disclosure, if “first” and “second”, etc. are referred to, it is only for the purpose of distinguishing technical features, and shall not be understood as indicating or implying relative importance or implying the number of the indicated technical features or implying the sequence of the indicated technical features.

In the description of the present disclosure, unless otherwise explicitly defined, the words such as “set”, “install”, and “connect” should be understood in a broad sense, and those of ordinary skill in the art can determine the specific meanings of the above words in the present disclosure in a rational way in combination with the specific contents of the technical solutions.

In the description of the present disclosure, the description of the reference term “some non-limiting embodiments” intends to be included in at least one embodiment or example of the present disclosure in combination with the specific characteristics, structures, materials or features of this embodiment or example. In this specification, the indicative expression of the above terms does not necessarily mean the same embodiment or example. Moreover, the described specific characteristics, structures, materials or features may be combined in any one or more embodiments or examples in a suitable manner.

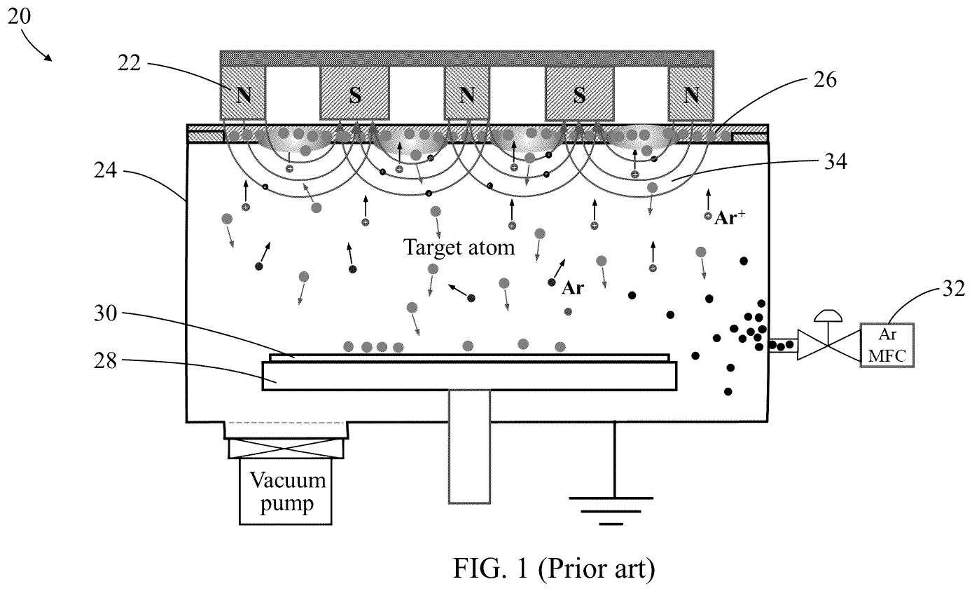

In the existing technology, the uniformity of thickness and resistivity of the coating formed on the substrate 200 will impact the production yield of the final coated product. To facilitate understanding, a typical magnetron sputtering device 20 in the existing technology will be first described with reference to FIG. 1, followed by an explanation of the fundamental magnetron sputtering principle. As shown in FIG. 1, the magnetron sputtering device 20 includes a magnetron 22, a vacuum chamber 24, a planar target 26 and a substrate pedestal 28. The substrate pedestal 28 is configured to hold a substrate 30 to be coated, with a front surface of the planar target 26 oriented toward the substrate pedestal 28. The magnetron 22 is mounted in back of the planar target 26 and is able to move relative to the planar target 26 via a drive mechanism. During magnetron sputtering operation, argon or other gases are admitted to the vacuum chamber with gas flow regulated by a mass flow controller 32. The magnetron 22 generates a magnetic field, while the negatively biased planar target 26 generates an electric field. Electrons move from the planar target 26 toward the substrate 30 or a mask plate within the vacuum chamber 24 under the action of the electric field, and during the movement, the electrons collide with argon atoms to ionize the argon atoms to generate argon ions and new electrons. The argon ions are accelerated as attracted by the electric field towards the planar target 26 to bombard a target surface to sputter atoms from the planar target 26. The sputtered atoms from the planar target are deposited onto a surface of the substrate 30, such that a film is formed on the substrate thereto. The secondary electrons generated during sputtering help maintain a plasma 34 across the surface of the planar target 26. Thereby, the Ar atom ionization and bombardment of argon ions as described above go on and on, and the deposition of a film by means of magnetron sputtering is performed successfully.

The PVD magnetron sputtering refers to a process wherein argon ions (Ar+) present in the plasma environment over the surface of the planar target 26 and controlled by the magnetron 22 bombards the planar target 26, to sputter out atoms from the planar target, and these sputtered atoms are directly deposited onto the substrate 30, or ionized prior to being deposited onto the substrate 30.

In the existing technologies, the thickness and resistance of the film coated onto the substrate 30 exhibit non-uniformity across the substrates. Resistivity, being material-dependent property, is defined as the product of the film thickness and the electrical resistance. Currently, the film thickness non-uniformity is typically addressed by selecting the planar target 26 and the magnetron 22 each with dimensions 1.5 times larger than the size of the substrate. This configuration enables coating of the entire substrate 30 by the magnetron 22 to ensure the film thickness uniform. However, this way usually requires an oversized magnetron 22. However, for such a large-sized magnetron 22, the resistance adjustment across the substrate can only be achieved by global adjustment of either the resistivity or the film thickness. In addition, resistivity values are related to parameters including the distance between the substrate 30 and the planar target 26, gas flow rate and other factors. In the existing technology, the resistivity control is typically implemented by adjusting the distance between the substrate 30 and the planar target 26 or adjusting the gas flow and other methods. However, the above-mentioned method needs to take a long time and only enable global resistivity change across the substrate, which does not help much with the problem of localized resistivity non-uniformity throughout the film. Consequently, how to maintain simultaneous thickness and resistivity uniformity of the film while enabling efficient film deposition is a puzzle in the industry.

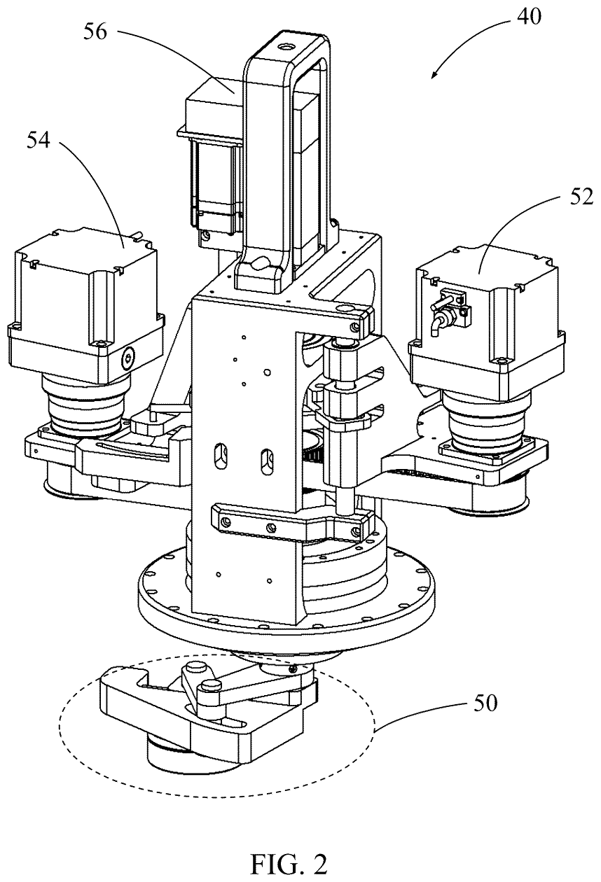

In view of the above-mentioned problem, with reference to FIGS. 2 to 7, a magnetron sputtering device 40 and a method for adjusting a rotation radius of a PVD magnetron 60 and a source power applied to a planar target 58 are proposed in the present disclosure. The magnetron sputtering device 40 with adjustable rotation radius of the PVD magnetron 60 and source power applied to the planar target 58 is hereinafter referred to as the device 40, and the magnetron sputtering method for adjusting the rotation radius of the PVD magnetron 60 and the source power applied to the planar target 58 is hereinafter referred to as the method. For ease of distinguishing the substrate 200, the substrate described in combination with the non-limiting embodiments in the present disclosure is marked as 200 and the substrate in described in combination with the existing technology is marked as 30.

The following continues to introduce the functions of device 40. The device 40 in the present disclosure enables the thickness and resistivity of the film on the substrate 200 to be maintained in their respective set ranges. The device 40 includes a magnetron rotating assembly 80, a drive mechanism, a controller, and a planar target 58. The controller is configured to control the drive mechanism to drive the magnetron rotating assembly 80 to move according to the thickness and resistivity of the film on the substrate 200. A relatively small magnetron 60 is adopted in the present disclosure, and specifically, a projection area of the magnetron 60 is smaller than a projection area of the planar target 58 on a horizontal plane. The magnetron is able to move relative to the planar target 58, and the controller is able to control the first drive unit 52 to drive the magnetron bracket 104 to rotate, such that the magnetron bracket 104 drives the magnetron 60 to rotate along a circumferential trajectory. Due to a relatively small volume of the magnetron 60, the magnetron 60 cooperates with the planar target 58 to create variable coating area: a circular coating area when the magnetron 60 is positioned near a center of the target or an annular coating area when the magnetron 60 operates along the circumferential trajectory. The controller is also able to actuate the second drive unit 54 to drive the magnetron 60 to perform radial movement relative to the planar target 58, thereby adjusting the rotation radius of the circumferential trajectory. It should be noted that during the magnetron 60 rotates along the circumferential trajectory, a portion of substrate 200 located within the circular or annular coating area may experience accelerated atom/ion accumulation relative to other portions of the substrate 200 within the same deposition time duration, that is, the thickness increases at an accelerated rate. In view of this, when a certain area of the substrate 200 exhibits relatively lower film thickness, the magnetron 60 can be driven to move radially, such that the magnetron 60 rotates over this area, thereby enabling the thickness of this area to increase at an accelerated rate, thereby mitigating thickness non-uniformity across the substrate.

In addition, the resistivity is also correlated with the source power supplied to the planar target 58. When the resistivity of a certain film area on the substrate 200 is lower than or higher than a standard value, the source power supplied to the planar target 58 is additionally controlled by the controller, and in conjunction with the magnetron 60 moving radially toward this area, thereby causing the resistivity of this area to approach the standard value. It should be noted that compared to adjusting the distance between the magnetron 60 and the planar target 58 or adjusting the gas flow rate, the source power adjustment demonstrates a significantly shorter response time than the aforementioned two methods, thereby enhancing operational efficiency and achieving precise control.

It should be noted that the film on the substrate 200 may present three scenarios: the first scenario occurs when the film exhibits nonuniform thickness in at least some areas while maintaining generally uniform resistivity across its entirety. In this case, the second drive unit 54 can be controlled by the controller to drive the magnetron 60 to move radially, and the magnetron 60 performs extended deposition in relatively low film thickness areas of the substrate 200, such that the thickness uniformity is achieved across the substrate. The second scenario arises when the film demonstrates substantially uniform overall thickness but non-uniform resistivity in at least some area. In this case, the source power applied to the planar target 58 can be adjusted by the controller, thereby improving resistivity uniformity across the substrate. The third scenario exists when both the thickness and resistivity are non-uniform in at least some areas of the film. In this case, on the one hand, it is necessary to control the magnetron 60 to perform extended deposition on relatively low film thickness area of the substrate 200, and on the other hand, it is necessary to synchronously regulate the source power applied to the planar target 58, such that both the thickness and resistivity of the film are brought within their respective specified ranges.

FIG. 2 illustrates an overall structure of the device 40. The device 40 includes a magnetron rotating assembly 80, a counterweight rotating assembly 90 and a drive mechanism. In some non-limiting embodiments, the drive mechanism includes a first drive unit 52 and a second drive unit 54, the first drive unit 52 is configured to drive the magnetron bracket 104 to rotate around a first axis, such that the magnetron 60 rotates relative to the planar target 58 along the circumferential trajectory, and the second drive unit 54 is configured to drive the magnetron 60 to move radially relative to the magnetron bracket 104, thereby adjusting the rotation radius of the circumferential trajectory. The drive mechanism further includes a third drive unit 56. The first drive unit 52 can be implemented as a first motor, the second drive unit 54 can be implemented as a second motor, the third drive unit 56 can be implemented as a third motor, and the first axis may be a vertical axis.

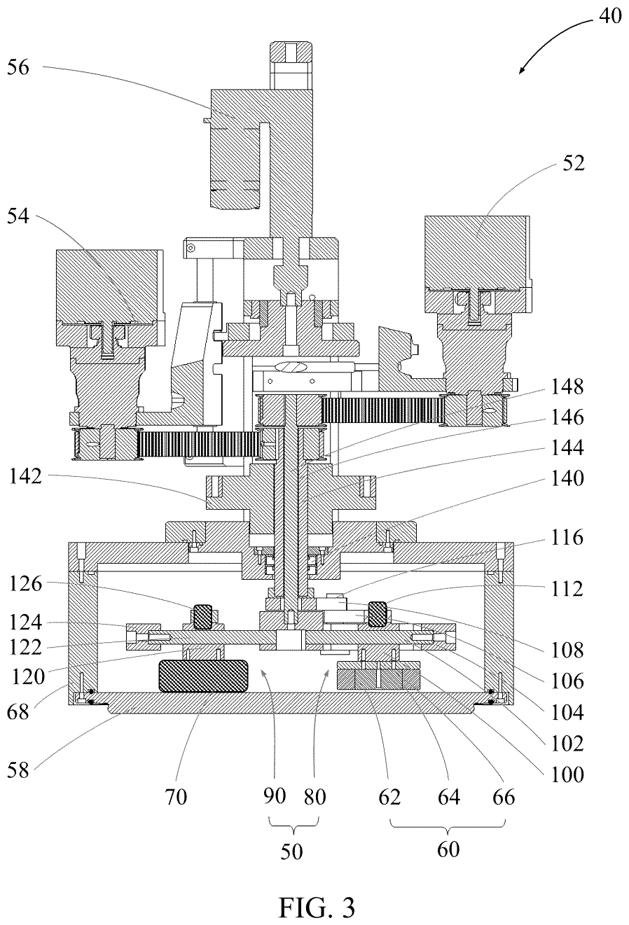

FIG. 3 depicts a cross-sectional view of the device 40. In some non-limiting embodiments, the device 40 further includes an adjustment assembly that is configured for adjusting the distance between a backing plate of the planar target 58 and the magnetron 60. The third drive unit 56 can serve as the power source for the adjustment assembly, so as to adjust the distance between the magnetron rotating assembly 80 and the backing plate of the planar target 58. The distance between the magnetron 60 and the planar target 58 is defined as a magnet-to-target distance. Further, the third drive unit 56 and a lifting mechanism can lift the magnetron rotating assembly 80 up and down, thereby adjusting the distance between the magnetron 60 and the planar target 58. The entire magnetron rotating assembly 80 can be operatively connected to the lifting mechanism, and the third drive unit 56 drives a lead screw of the lifting mechanism to raise or lower the lifting mechanism. A cooling water tank 68 and the planar target 58 can be designed with a dovetail sliding interface, that is, the cooling water tank 68 is provided with a slot in which the planar target 58 can slide, such that the planar target 58 can move away from or close to the magnetron 60. After positional adjustment, the planar target 58 can be locked with a fastener such as a bolt to prevent the planar target 58 from unintended displacement. However, this method presents technical challenges due to the large dimensions of the planar target, which necessitates a relatively extensive sealing area.

Still referring to FIG. 3, in some non-limiting embodiments, the magnetron 60 includes a first magnet 62, a second magnet 64 and a magnet yoke 66. The magnetron 60 can be configured in various shapes, such as circular, oval, and other configurations. The first magnet 62 and the second magnet 64 are arranged with opposite magnetic polarities.

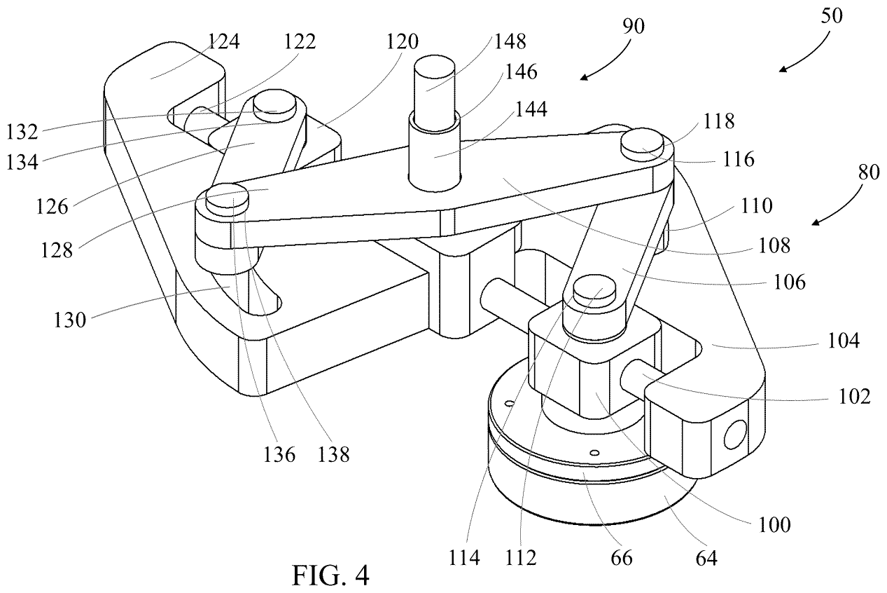

Still referring to FIGS. 3 and 4, FIG. 3 illustrates the structure of the magnetron rotating assembly 80, and FIG. 4 shows a perspective view of the magnetron rotating assembly 80. In some non-limiting embodiments, the magnetron rotating assembly 80 includes a magnetron 60, a magnetron slider 100, a magnetron guide rail 102 and a magnetron bracket 104. The magnetron guide rail 102 can be implemented as a linear slide rod as shown in the figure, and the first drive unit 52 can drive the magnetron bracket 104 to rotate around the first axis, such that the magnetron 60 rotates relative to the planar target 58 along the circumferential trajectory. When the magnetron 60 rotates relative to the planar target 58 along the circumferential trajectory, a circular or annular coating area is formed with the planar target 58.

Based on the above-mentioned structure, the drive mechanism further includes a first link 106 and a second link 108, where the first link 106 is pivotally connected at both ends to the second link 108 and the magnetron slider 100, respectively. The second link 108 is able to rotate around a second axis, such that the magnetron 60 is driven to move radially via the first link 106 to adjust the rotation radius of the circumferential trajectory. The second axis may also be a vertical axis, that is, the first axis and the second axis are parallel to each other.

More specifically, the drive mechanism further includes a first shaft 144 and a second shaft 148, the first shaft 144 is connected to a shaft output end of the first drive unit 52 and the magnetron bracket 104, and the second shaft 148 is connected to a shaft output end of the second drive unit 54 and the second link 108. The first shaft 144 and the second shaft 148 are arranged in a coaxial arrangement, at this time the first axis coincides with the second axis. The first drive unit 52 can drive the first shaft 144 to rotate, such that the magnetron 60 rotates along the circumferential trajectory, and the second drive unit 54 can drive the second shaft 148 to rotate, thereby adjusting the rotation radius of the magnetron 60.

Still referring to FIG. 3, in some non-limiting embodiments, the device 40 further includes a cooling water tank 68, and circulating cooling water is filled in the cooling water tank 68 to cool the planar target 58. A storage cavity of the cooling water tank 68 needs sealing. Compared to separately sealing the second shaft 148 and the first shaft 144, the second shaft 148 in this embodiment adopts a coaxial design where the second shaft 148 is concentrically mounted around the first shaft 144, thus the sealing complexity is relatively low and the sealing performance can be improved. In addition, the sealing performance of the cooling water tank 68 can also be improved through a skeleton oil seal 140 or a magnetic fluid sealing shaft 142. The first shaft 144 defines a fifth through hole 146, through which the second shaft 148 passes to form a coaxial arrangement with the first shaft 144, thereby simplifying the structure of the device 40.

FIG. 4 illustrates a magnetron and a counterweight rotating assembly 50. The interconnection between components within the magnetron rotating assembly 80 will be described in detail below. The magnetron slider 100 is slidably connected to the magnetron guide rail 102, such that the magnetron 60 can slide on the magnetron bracket 104 to adjust the radius of the circumferential trajectory. The first link 106 is connected at both ends to the magnetron slider 100 and the second link 108, respectively. The first shaft pin 112 extends through a first through hole 114 to connect the first link 106 to the magnetron slider 10, and the second shaft pin 116 extends through a second through hole 118 to connect the second link 108 to the first link 106.

When the second shaft 148 rotates, it drives the second link 108 to rotate, which in turn drives the first link 106 to rotate. This motion imposes a push or pull force on the magnetron slider 100. As the magnetron slider 100 is constrained to slide along the magnetron guide rail 102 only, the rotation of the second shaft 148 can be converted into a radial reciprocating movement of the magnetron slider 100, thereby achieving the adjustment of the rotation radius. It should be noted that since the sliding of the magnetron 60 and the rotation of the magnetron 60 are independently driven by two separate drive units, thereby enabling simultaneous adjustment of the rotation radius of the magnetron 60 during circumferential scanning operations, without shutdown for adjustment, which is conductive to film deposition efficiency.

In addition, in some non-limiting embodiments, the magnetron bracket 104 defines a first arc-shaped groove 110, and an end of the second shaft pin 116 protrudes from a surface of the first link 106 and is positioned in the first arc-shaped groove 110. The first arc-shaped groove 110 can guide the second shaft pin 116, such that the second shaft pin 116 slides along a wall of the first arc-shaped groove 110, thus ensuring that the first link 106 moves along a preset trajectory.

When the magnetron 60 rotates at a high speed, eccentric rotation caused by off-center mass distribution would cause vibration. In view of this, still referring to FIGS. 3 and 4, in some non-limiting embodiments, the device 40 further includes a counterweight rotating assembly 90 that is configured to effectively mitigate the vibration generated when the magnetron 60 rotates. Specifically, the counterweight rotating assembly 90 includes a counterweight block 70, a counterweight slider 120, a counterweight guide rail 122 and a counterweight bracket 124. The counterweight block 70 is slidably connected to the counterweight bracket 124 via the counterweight guide rail 122 and the counterweight slider 120. The first drive unit 52 is configured to drive the counterweight bracket 124 to rotate around the first axis, such that the counterweight block 70 rotates along a circumferential trajectory. The second drive unit 54 is configured to drive the counterweight block 70 to move radially relative to the counterweight bracket 124. The counterweight block 70 and the magnetron 60 move synchronously in opposite directions, and the counterweight block 70 and the magnetron 60 are symmetrically arranged, that is, the counterweight block 70 and the magnetron 60 rotate along a shared coaxial circumferential trajectory, thereby reducing the vibration of the magnetron 60.

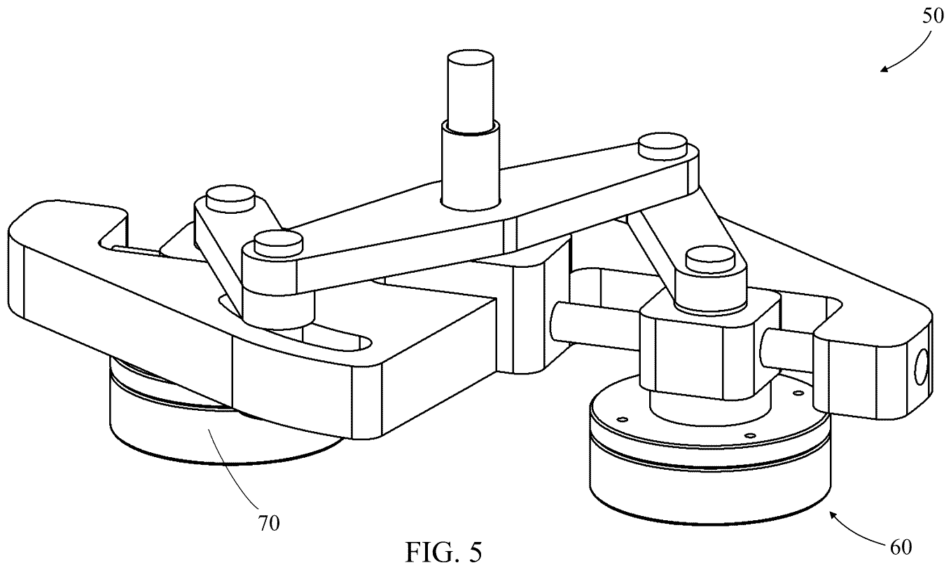

Referring to FIGS. 4 and 5, the interconnection between components within the counterweight rotating assembly 90 will be described below. Both ends of the third link 126 are connected to the counterweight slider 120 and a fourth link 128, respectively, where a third shaft pin 132 extends through a third through hole 134 such that the third link 126 is connected to the counterweight slider 120, and a fourth shaft pin 136 extends through a fourth through hole 138 such that the fourth link 128 is connected to the third link 126. The drive method for the counterweight slider 120 can be understood with reference to the drive method for the magnetron slider 100, which will not be elaborated here.

In some non-limiting embodiments, the fourth link 128 and the second link 108 can be integrally joined as a unitary link. In another non-limiting embodiment, the fourth link 128 and the second link 108 can be a split structure and fastened together via a further connecting component. In any case, when the second drive unit 54 drives the second shaft 148 to rotate, the fourth link 128 and the second link 108 can rotate synchronously, such that the radial displacement of the counterweight block 70 maintains a consistent radial displacement relative to the magnetron 60.

Similarly, the magnetron bracket 104 and the counterweight bracket 124 can be integrally joined as a unitary bracket. Alternatively, the magnetron bracket 104 and the counterweight bracket 124 can be a split structure and fastened together via a further connecting component. In any case, when the first drive unit 52 drives the first shaft 144 to rotate, the magnetron bracket 104 and the counterweight bracket 124 can rotate synchronously.

In addition, in some non-limiting embodiments, the counterweight bracket 124 defines a second arc-shaped groove 130, and an end of the fourth shaft pin 136 protrudes from a surface of the third link 126 and is positioned in the second arc-shaped groove 130. The second arc-shaped groove 130 can guide the fourth shaft pin 136, such that the fourth shaft pin 136 slides along a wall of the second arc-shaped groove 130, thus ensuring that the third link 126 moves along a preset trajectory.

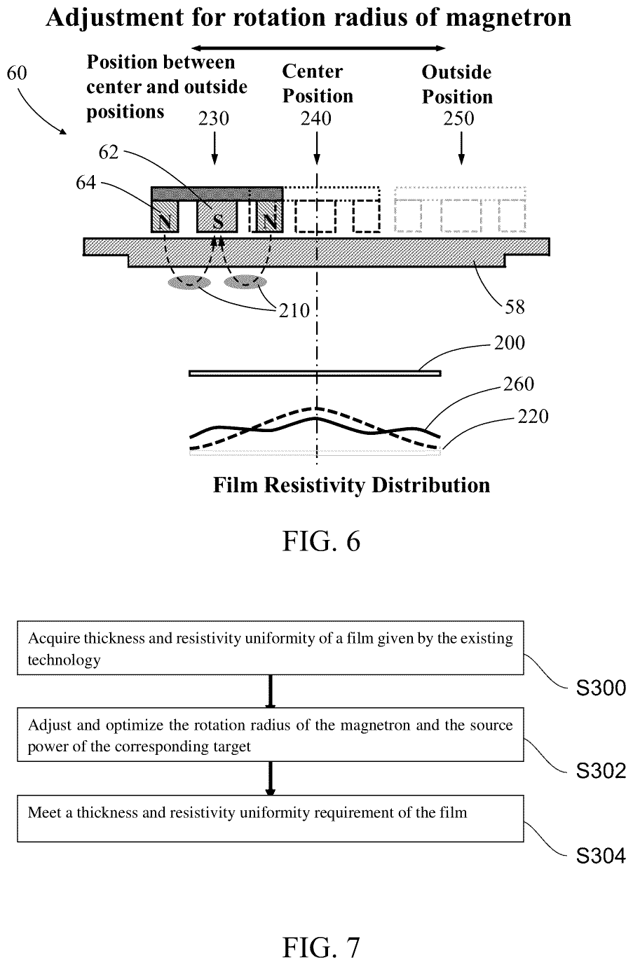

FIG. 6 depicts a schematic diagram showing that the magnetron 60 moves radially to adjust the rotation radius of the circumferential trajectory. Taking the example shown in the figure, the magnetron 60 can be switched among three positions, that is, an intermediate position 230 located midway between center and outside positions, a center position 240 (the innermost position of a movement path of the magnetron 60 on the magnetron guide rail 102, and in such case, the magnetron 60 rotates along a circumferential trajectory with the minimum rotation radius) and an outside position 250 (the outermost position of the movement path of the magnetron 60 on the magnetron guide rail 102, and in such case, the magnetron 60 rotates along a circumferential trajectory with the maximum rotation radius). It should be noted that due to the circular motion trajectory of the magnetron 60, the intermediate position 230, the center position 240 and the outside position 250 can correspond to concentric annular zones (inner ring, center, and outer ring) of the magnetron 60. The magnetron 60 marked by the solid line in the figure indicates the magnetron 60 positioned in the inner ring while moving toward the left side of the figure, and the magnetron 60 marked by the dotted line in the figure indicates the magnetron 60 already positioned in the outer ring while moving toward the right side of the figure. The dwell time at different radial positions is controlled to compensate for the inherent variation in deposition rate across the substrate 200, thereby achieving a uniform coating thickness.

In addition, FIG. 6 further shows the film resistivity distribution. The illustrated figure shows that the film resistivity gradually decreases from the center toward both sides (as represented by the dotted-line curve), indicating non-uniform distribution. In such case, this problem can be addressed in a manner of adjusting the source power. Specifically, the relationship between the source power and resistivity can be obtained in advance. When the magnetron 60 moves to different positions of the rotation radius, the source power applied to the planar target 58 is adaptively adjusted, causing a resistivity uniformity across the substrate. Taking the example shown in the figure, for of the given film material, the higher the source power, the lower the resistivity. Therefore, when the magnetron 60 is switched to the center position 240, maximum source power is applied to the planar target 58, and when the magnetron 60 is switched to the intermediate position 230 and the outside position 250 in sequence (from the central position), the source power applied to the planar target 58 gradually decreases, achieving a relatively uniform resistivity distribution (as represented by the solid line curve).

It should be noted that if a certain area of the film exhibits a relatively higher or relatively lower resistivity, however, the thickness is within the normal range, the operational duration of the magnetron 60 in that area can be shortened while adjusting the resistivity in the area, to prevent the thickness in this area from increasing too fast and exceeding the normal range.

In addition to the PVD device 40 with adjustable rotation radius of the PVD magnetron 60 and source power applied to the planar target 58, a method for adjusting a rotation radius of a PVD magnetron 60 and a source power applied to a planar target 58 is further proposed in the present disclosure. In some non-limiting embodiments, the method for adjusting the rotation radius of the PVD magnetron 60 and the source power applied to the planar target 58 includes the following steps:
providing the magnetron 60 and the planar target 58, where a horizontal projection area of the magnetron 60 is smaller than a horizontal projection area of the planar target 58, and the magnetron 60 is able to rotate around a first axis relative to the planar target 58; and
adjusting the rotation radius of the magnetron 60, and/or adjusting the source power applied to the planar target 58 to maintain both a thickness and a resistivity of a film within their respective set ranges.

Specifically, the deposition rate at different regions of the substrate 200 can be adjusted by changing the rotation radius of the magnetron 60, thereby adjusting the thickness of the film. The resistivity of different parts of the film can be adjusted by changing a power supply to a planar target and switching the magnetron 60 among different radial positions. In this way, both the thickness and resistivity uniformity of the film can meet the requirements.

Further, please refer to FIG. 7, in some non-limiting embodiments, the method steps include:
S300: acquiring thickness and resistivity uniformity of the film given by the existing technology;
S302: adjusting and optimizing the rotation radius of the magnetron 60 and the source power applied to the corresponding planar target 58; and
S304: meeting a thickness and resistivity uniformity requirement of the film.

In an example, when the thickness of the film in a central area is relatively large, the rotation radius of the magnetron 60 can be increased to accelerate deposition in other regions of the film relative to the central area, thereby reducing or eliminating thickness variance between different areas.

In another example, when the resistivity in the central area of the film exceeds the normal range, the magnetron 60 can be positioned over this area, and the source power applied to the planar target 58 can be adjusted to reduce or eliminate resistivity variance between different areas.

The above describes a method to homogenize the film thickness and resistivity by adjusting the rotation radius of the magnetron 60 and changing the source power applied to the planar target 58. In addition, in some non-limiting embodiments, before changing the rotation radius of the magnetron 60, the method proposed by the present disclosure further includes the following steps: identifying the thickness and resistivity across the substrate, obtaining thickness distribution information and resistivity distribution information of the film, and performing adaptive adjustments according to the aforementioned adjusting strategy and based on the thickness distribution information and the resistivity distribution information.

The method for identifying the thickness and resistivity across the substrate includes: preparing a sample according to a normal production process, analyzing a coating film thickness and resistivity of the sample, and establishing a database. Specifically, for the thickness, the sample can be cut to form a cross section, and then the thickness at different positions along the cross section is measured with the help of a microscope and other equipment. For the resistivity, the resistance of each part of the sample can be detected by a resistance detection equipment, and the resistance is multiplied by the thickness to obtain the resistivity across the substrate.

The embodiments of the present disclosure are described in detail above in combination with the drawings, and however, the present disclosure is not limited the above embodiments. Under the premise of not departing from the purpose of the present disclosure, various changes may also be made within the knowledge scope of those skilled in the art. In addition, the embodiments in the present disclosure and features in the embodiments may be combined with each other without conflict.

1. A physical vapor deposition (PVD) device with adjustable rotation radius of magnetron and source power of a planar target configured to form a film on a substrate, the device comprising:
a planar target;
a magnetron rotating assembly, comprising a magnetron, a magnetron bracket, a magnetron guide rail and a magnetron slider, wherein the magnetron is slidably connected to the magnetron bracket via the magnetron guide rail and the magnetron slider, and wherein a projection area of the magnetron on a horizontal plane is smaller than a projection area of the planar target on the horizontal plane;
a drive mechanism, comprising a first drive unit and a second drive unit, wherein the first drive unit is configured to drive the magnetron bracket to rotate around a first axis, such that the magnetron rotates relative to the planar target along a circumferential trajectory, and the second drive unit is configured to drive the magnetron to move radially relative to the magnetron bracket, thereby adjusting a rotation radius of the circumferential trajectory; and
a controller configured to perform at least one of the following control logics:
controlling the second drive unit to drive the magnetron to move radially, such that the film is formed with a thickness within a set thickness range; or
controlling a source power applied to the planar target, such that the film is formed with a resistivity within a set resistivity range.

2. The device according to claim 1, wherein the drive mechanism further comprises a first link and a second link, the first link is rotatably connected at both ends to the second link and the magnetron slider, respectively, and the second link is capable of rotating around a second axis, such that the magnetron is driven to move radially via the first link to adjust the rotation radius of the circumferential trajectory, and wherein the first axis and the second axis are disposed in parallel.

3. The device according to claim 2, wherein the drive mechanism further comprises a first shaft and a second shaft, the first shaft is connected to a shaft output end of the first drive unit and the magnetron bracket, and the second shaft is connected to a shaft output end of the second drive unit and the second link; and wherein
the first shaft and the second shaft are arranged coaxially, the first axis coincides with the second axis, the first drive unit is capable of driving the first shaft to rotate, such that the magnetron rotates relative to the planar target along the circumferential trajectory, and the second drive unit is capable of driving the second shaft to rotate to adjust the rotation radius of the magnetron.

4. The device according to claim 2, wherein the drive mechanism further comprises a first shaft pin, and the magnetron slider is rotatably connected to the first link via the first shaft pin.

5. The device according to claim 2, wherein the drive mechanism further comprises a second shaft pin, and the first link is rotatably connected to the second link via the second shaft pin; and wherein
the magnetron bracket defines a first arc-shaped groove, an end of the second shaft pin protrudes from a surface of the first link and is positioned in the first arc-shaped groove, and the first arc-shaped groove is capable of guiding the second shaft pin.

6. The device according to claim 1, further comprising a counterweight rotating assembly, wherein the counterweight rotating assembly comprises a counterweight block, a counterweight bracket, a counterweight guide rail and a counterweight slider, and the counterweight block is slidably connected to the counterweight bracket via the counterweight guide rail and the counterweight slider;
the first drive unit is configured to drive the counterweight bracket to rotate around the first axis, such that the counterweight block rotates along the circumferential trajectory, and the second drive unit is configured to drive the counterweight block to move radially relative to the counterweight bracket; and wherein
the counterweight block and the magnetron move synchronously and in opposite directions, and the counterweight block and the magnetron are symmetrically arranged.

7. The device according to claim 6, wherein the drive mechanism further comprises a first link and a second link, the first link is rotatably connected at both ends to the second link and the magnetron slider, respectively, and the second link is capable of rotating around the second axis, such that the magnetron is driven to move radially via the first link to adjust the rotation radius of the circumferential trajectory; and
the drive mechanism further comprises a third link and a fourth link, the third link is rotatably connected at both ends to the fourth link and the counterweight slider, respectively, and the fourth link and the second link are capable of rotating synchronously around the second axis, such that the counterweight block is driven to move radially via the third link to adjust the rotation radius of the circumferential trajectory

8. The device according to claim 1, further comprising an adjustment assembly, wherein the adjustment assembly is configured to adjust a distance between a backing plate of the planar target and the magnetron.

9. A method for adjusting a rotation radius of a PVD magnetron and source power applied to a planar target, applied to form a film on a substrate, the method comprising the following steps:
providing the magnetron and the planar target, wherein a projection area of the magnetron on a horizontal plane is smaller than a projection area of the planar target on the horizontal plane, and the magnetron is capable of rotating around a first axis relative to the planar target; and
performing at least one of the following: adjusting the rotation radius of the magnetron, or adjusting a source power applied to the planar target, such that the film is formed with a thickness and a resistivity each within their respective set ranges.

10. The method according to claim 9, further comprising:
acquiring thickness distribution information and resistivity distribution information of the film; and
performing, based on the thickness distribution information and the resistivity distribution information, at least one of the following: adjusting the rotation radius of the magnetron, or adjusting the source power applied to the planar target.
